(19) United States
(12) Patent Application Publication
(10) Pub. No.: US 2025/0246523 A1
(43) Pub. Date: Jul. 31, 2025

(54) SEMICONDUCTOR DEVICE

(71) Applicant: FUJI ELECTRIC CO., LTD., Kawasaki-shi (JP)

(72) Inventor: Kensuke MATSUZAWA, Matsumoto-city (JP)

(73) Assignee: FUJI ELECTRIC CO., LTD., Kawasaki-shi (JP)

(21) Appl. No.: 18/962,462

(22) Filed: Nov. 27, 2024

(30) Foreign Application Priority Data
Jan. 31, 2024 (JP) 2024-013228

(51) Int. Cl. H01L 23/495; H01L 23/31

(52) U.S. Cl. CPC H01L 23/49555; H01L 23/3107

(57) ABSTRACT

A semiconductor device includes: a semiconductor chip; a sealing resin provided to seal the semiconductor chip; a first terminal extending from the sealing resin in a first direction so as to have a first connection part projecting to an outside of the sealing resin; and a second terminal extending from the sealing resin in the first direction so as to have a second connection part projecting to the outside of the sealing resin, wherein the first terminal and the second terminal have rectangular opposed parts separately opposed to each other between the first connection part and the second connection part, and the respective opposed parts have a width in a range of 1 millimeter or greater and 13 millimeters or smaller in a second direction perpendicular to the first direction.

### CROSS-REFERENCE TO RELATED APPLICATION

This application claims benefit of priority under 35 USC 119 based on Japanese Patent Application No. 2024-013228 filed on Jan. 31, 2024, the entire contents of which are incorporated by reference herein.

### BACKGROUND OF THE INVENTION

### 1. Field of the Invention

The present disclosure relates to semiconductor devices (power semiconductor modules).

### 2. Description of the Related Art

WO2014/002442A1 discloses a configuration in which a P-terminal and an N-terminal each have a convex shape at a position overlapping with each other. JP2007-299781A discloses a configuration in which a direct-current positive-electrode plate-shaped conductor and a direct-current negative-electrode plate-shaped conductor are arranged with the respective surfaces opposed to each other. JPH06-21323A discloses that two power-supply terminals made of plate-shaped conductors that transmit positive and negative power-supply potentials are tightly attached together with an insulating sheet of an insulator including synthetic resin interposed, in which the insulating sheet has a thickness set in a range of 0.5 millimeters to 1.5 millimeters.

JP7180812B1 discloses an power converter that includes a capacitor including a positive electrode terminal, a negative electrode terminal arranged to face the positive electrode terminal with a first gap, and a first insulating member arranged in the first gap, and a semiconductor module including a positive electrode input terminal overlapping with and connected to the positive electrode terminal, a negative electrode input terminal arranged to face the positive electrode input terminal with a second gap and overlapping with and connected to the negative electrode terminal, and a second insulating member arranged between the positive electrode input terminal and the negative electrode input terminal and including a contact surface in contact with either a front surface or a back surface of the first insulating member, a second busbar being fitted with a first busbar, in which the respective positive and negative electrode terminals and the respective first and second busbars are fastened to each other with a single screw and a washer.

WO2019/239771A1 discloses a configuration in which the respective terminals are bent so as to be fastened together with a bolt and a nut. JP2022-006780A discloses a configuration in which terminals of a main circuit are arranged to be opposed parallel and adjacent to each other in order to reduce wiring inductance. JP2018-190965A discloses a configuration in which an insulation device is interposed between first and second direct-current voltage terminal elements and first and second direct-current voltage connection elements.

Development of power semiconductor modules has been promoted that have a configuration in which a plurality of terminals are arranged (laminated) so as to be opposed to each other in order to reduce inductance.

However, the arrangement of the plural terminals to be opposed to each other impedes facilitation of screw fastening between the plural terminals and an external member such as a capacitor.

### SUMMARY OF THE INVENTION

In view of the foregoing problems, the present disclosure provides a semiconductor device having a configuration capable of reducing inductance and also facilitating screw fastening between terminals.

An aspect of the present disclosure inheres in a semiconductor device including: a semiconductor chip; a sealing resin provided to seal the semiconductor chip; a first terminal extending from the sealing resin in a first direction so as to have a first connection part projecting to an outside of the sealing resin; and a second terminal extending from the sealing resin in the first direction so as to have a second connection part projecting to the outside of the sealing resin, wherein the first terminal and the second terminal have rectangular opposed parts separately opposed to each other between the first connection part and the second connection part, and the respective opposed parts have a width in a range of 1 millimeter or greater and 13 millimeters or smaller in a second direction perpendicular to the first direction.

### BRIEF DESCRIPTION OF THE DRAWINGS

FIG. 1 is a plan view illustrating a semiconductor device according to a first embodiment;

FIG. 2 is a perspective view illustrating the semiconductor device according to the first embodiment;

FIG. 3 is a cross-sectional view taken along line A-A′ in FIG. 1;

FIG. 4 is another cross-sectional view taken along line A-A′ in FIG. 1;

FIG. 5 is a plan view illustrating the semiconductor device according to the first embodiment;

FIG. 6 is another plan view illustrating the semiconductor device according to the first embodiment;

FIG. 7 is a cross-sectional view taken along line B-B′ in FIG. 5;

FIG. 8 is a cross-sectional view taken along line C-C′ in FIG. 5;

FIG. 9 is another cross-sectional view taken along line C-C′ in FIG. 5;

FIG. 10 is an equivalent circuit diagram of the semiconductor device according to the first embodiment;

FIG. 11 is a cross-sectional view illustrating a semiconductor device of a first comparative example;

FIG. 12 is a plan view illustrating the semiconductor device of the first comparative example;

FIG. 13 is a plan view illustrating a semiconductor device of a second comparative example;

FIG. 14 is a table showing a relation between inductance and each of a laminate width and a fastening-point distance;

FIG. 15 is a table showing a relation between inductance and each of a laminate width and a P-N distance;

FIG. 16 is a perspective view illustrating a semiconductor device according to a second embodiment;

FIG. 17 is a cross-sectional view illustrating the semiconductor device according to the second embodiment;

FIG. 18 is a cross-sectional view illustrating a semiconductor device according to a third embodiment;

FIG. 19 is a cross-sectional view illustrating a semiconductor device according to a fourth embodiment;

FIG. 20 is a cross-sectional view illustrating a semiconductor device according to a fifth embodiment;

FIG. 21 is a cross-sectional view illustrating a semiconductor device according to a sixth embodiment; and

FIG. 22 is a cross-sectional view illustrating a semiconductor device according to a seventh embodiment.

### DETAILED DESCRIPTION

With reference to the drawings, first to seventh embodiments of the present disclosure will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

Additionally, definitions of directions such as “upper”, “lower”, “upper and lower”, “left”, “right”, and “left and right” in the following description are simply definitions for convenience of description, and do not limit the technological concept of the present disclosure. For example, when observing an object rotated by 90°, the “upper and lower” are converted to “left and right” to be read, and when observing an object rotated by 180°, the “upper and lower” are read reversed, which should go without saying. In addition, a “top surface” and a “bottom surface” may be read as “front surface” and “back surface” respectively. In addition, the “first main surface” and the “second main surface” of each member are main surfaces facing each other. For example, if the “first main surface” is the top surface, the “second main surface” is the bottom surface. In addition, the “first main surface” and the “second main surface” may be read as “one main surface” and “another main surface” respectively.

In the present specification, a term “first terminal” refers to either a positive electrode terminal or a negative electrode terminal of a power semiconductor module, and a term “second terminal” refers to the other one of the positive electrode terminal and the negative electrode terminal of the power semiconductor module. Namely, when the “first terminal” is the positive electrode terminal of the power semiconductor module, the “second terminal” is the negative electrode terminal. When the “first terminal” is the negative electrode terminal of the power semiconductor module, the “second terminal” is the positive electrode terminal.

### FIRST EMBODIMENT

### Configuration of Semiconductor Device

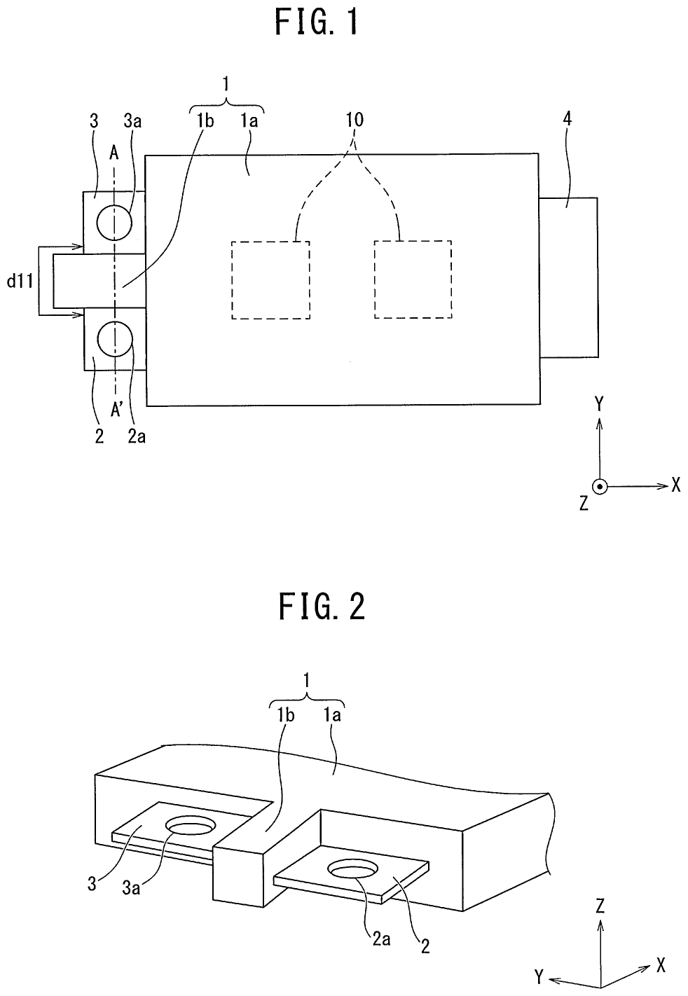

A first embodiment is illustrated below with a semiconductor device that is a “2-in-1” power semiconductor module having functions for two power semiconductor elements. FIG. 1 is a plan view illustrating the semiconductor device according to the first embodiment. As illustrated in FIG. 1, the semiconductor device according to the first embodiment includes power semiconductor elements (semiconductor chips) 10, a sealing resin 1 provided to seal the semiconductor chips 10, a positive electrode terminal (a P terminal) 2 that is a first terminal, a negative electrode terminal (an N terminal) 3 that is a second terminal, and an output terminal (a U terminal) 4 that is a third terminal, in which the respective terminals extend to further project to the outside of the sealing resin 1. FIG. 1 schematically indicates, by the broken lines, the semiconductor chips 10 sealed inside the sealing resin 1.

The semiconductor chips 10 are each made of a semiconductor substrate including silicon (Si), silicon carbide (SiC), gallium nitride (GaN), gallium oxide (Ga₂O₃), or diamond (C), for example. The respective semiconductor chips 10 as used herein may be a field-effect transistor (FET) such as a MOSFET, an insulated gate bipolar transistor (IGBT), a static induction (SI) thyristor, or a gate turn-off (GTO) thyristor. The type, the arranged positions, and the number of the semiconductor chips 10 may be changed as appropriate.

The sealing resin 1 includes resin material such as epoxy resin or silicone. The sealing resin 1 may be formed by transfer molding with no case used. The sealing resin 1 may include a resin case and resin filled inside the case by potting. The sealing resin 1 includes a body part 1a having a substantially cuboidal outline, and a projecting part 1b projecting from the body part 1a. The outline of the body part 1a is not limited to the substantially cuboidal shape, and may be any solid shape. The projecting part 1b projects from the body part 1a on the same side as the positive electrode terminal 2 and the negative electrode terminal 3 so as to extend outward between the positive electrode terminal 2 and the negative electrode terminal 3. The projecting part 1b extends to the outside farther than the positive electrode terminal 2 and the negative electrode terminal 3. The provision of the projecting part 1b between the positive electrode terminal 2 and the negative electrode terminal 3 can ensure a creepage distance d11 between the positive electrode terminal 2 and the negative electrode terminal 3 along the side surfaces of the projecting part 1b. The creepage distance d11 is in a range of about 5 millimeters or longer and 15 millimeters or smaller, for example.

In the present description, the right-left direction in FIG. 1 in which the positive electrode terminal 2, the negative electrode terminal 3, and the output terminal 4 extend to further project outward from the sealing resin 1 is defined as an X-axis direction, and the rightward direction in FIG. 1 is defined as the forward direction of the X axis. The upper-lower direction in FIG. 1 perpendicular to the X-axis direction is defined as a Y-axis direction, and the upward direction in FIG. 1 is defined as the forward direction of the Y axis. The frontward direction and the backward direction in FIG. 1 perpendicular to the X-axis direction and the Y-axis direction are defined as a Z-axis direction, and the frontward direction in FIG. 1 is defined as the forward direction of the Z axis. The same definitions are also applied to the following explanations regarding the other drawings.

The positive electrode terminal 2 and the negative electrode terminal 3 project from the same side of the body part 1a of the sealing resin 1. The output terminal 4 projects from the opposite side of the positive electrode terminal 2 and the negative electrode terminal 3. The positive electrode terminal 2, the negative electrode terminal 3, and the output terminal 4 are each a plate-shaped conductor having a first main surface (the top surface) and a second main surface (the bottom surface) opposed to each other in the Z-axis direction. The positive electrode terminal 2, the negative electrode terminal 3, and the output terminal 4 each have a thickness in a range of about one millimeter or greater and three millimeters or smaller, for example. The positive electrode terminal 2, the negative electrode terminal 3, and the output terminal 4 each include conductive material such as copper (Cu), a Cu alloy, aluminum (Al), or an Al alloy. The positive electrode terminal 2, the negative electrode terminal 3, and the output terminal 4 are external terminals that are electrically connected to the semiconductor chips 10 and can be connected to external members.

The positive electrode terminal 2 includes a connection part 2a that can be connected to an external member such as a capacitor. The negative electrode terminal 3 includes a connection part 3a that can be connected to an external member such as a capacitor. FIG. 1 illustrates a case in which the connection parts 2a and 3a are each a fastening hole for enabling screw fastening. The screw fastening facilitates a connection to a busbar and ensures stable fastening force by controlling torque, so as to enable the facilitation of handling. The connection parts 2a and 3a are not necessarily provided with the fastening holes, but may each be a region that can be connected to an external member by laser welding instead. The structure of the positive electrode terminal 2 and the negative electrode terminal 3 thus allows the choice between the screw fastening and the laser welding for the connection to the external member.

FIG. 2 is a perspective view illustrating the semiconductor device according to the first embodiment. FIG. 2 illustrates a case in which the positive electrode terminal 2 and the negative electrode terminal 3 are shifted from each other and arranged at different heights in the Z-axis direction. The present embodiment is illustrated with the case in which the positive electrode terminal 2 is located on the lower side in the Z-axis direction (in the reverse direction of the Z axis), and the negative electrode terminal 3 is located on the upper side in the Z-axis direction (in the forward direction of the Z axis).

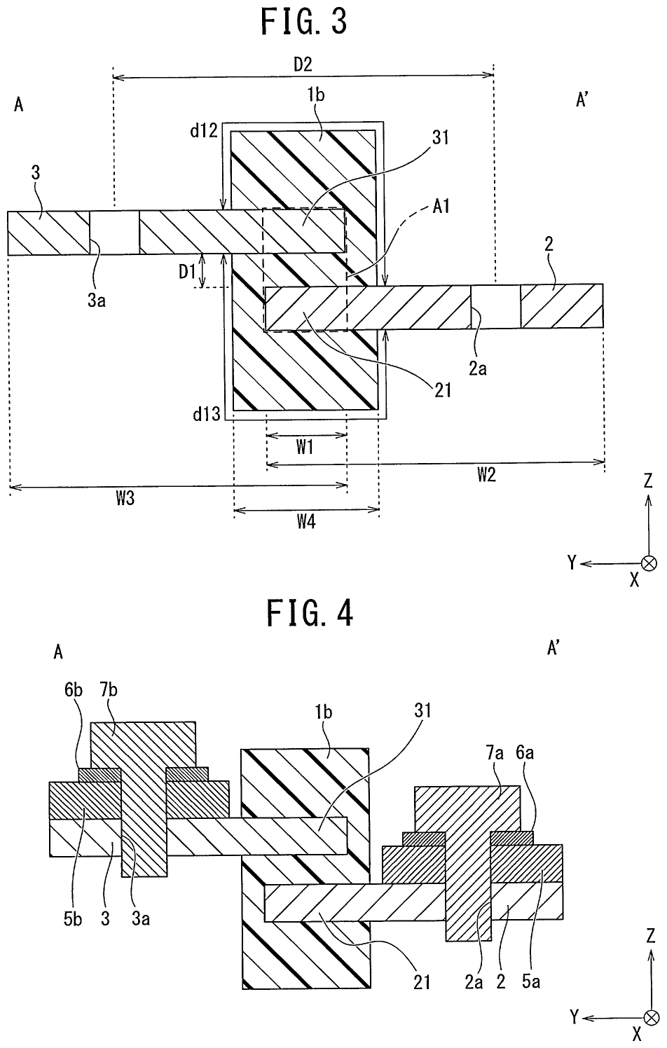

FIG. 3 is a cross-sectional view in the Y-axis direction parallel to the line A-A′ passing through the positive electrode terminal 2, the projecting part 1b, and the negative electrode terminal 3 illustrated in FIG. 1. As illustrated in FIG. 3, the parts of the positive electrode terminal 2 and the negative electrode terminal 3 located adjacent to each other are buried inside the projecting part 1b.

The positive electrode terminal 2 has a width W2 in the Y-axis direction. The negative electrode terminal 3 has a width W3 in the Y-axis direction. The respective widths W2 and W3 may be either common to or different from each other. The respective widths W2 and W3 are set in a range of about 10 millimeters or greater and 30 millimeters or smaller, for example.

A part (an opposed part) 21 of the positive electrode terminal 2 and a part (an opposed part) 31 of the negative electrode terminal 3 are located adjacent to each other (laminated) so as to be opposed to (overlap with) each other with a gap provided in the Z-axis direction. FIG. 3 schematically indicates, by the broken line, a region (an opposed area) A1 in which the opposed part 21 of the positive electrode terminal 2 and the opposed part 31 of the negative electrode terminal 3 are opposed to each other. A current flows through each of the positive electrode terminal 2 and the negative electrode terminal 3 in the opposite directions. The mutual inductance in the opposed area A1 can reduce wiring inductance upon the flow of the current.

A width (also referred to below as a “laminate width”) W1 of each of the opposed part 21 of the positive electrode terminal 2, the opposed part 31 of the negative electrode terminal 3, and the opposed area A1 in the Y-axis direction is in a range of 1 millimeter or greater and 13 millimeters or smaller, for example, or may be in a range of about 1 millimeter or greater and 9 millimeters or smaller or in a range of about 1 millimeter or greater and 5 millimeters or smaller. Setting the laminate width W1 to about 1 millimeter or greater can exhibit the effect of reducing the inductance. The greater laminate width W1 can further enhance the effect of reducing the inductance.

The projecting part 1b of the sealing resin 1 covers the opposed part 21 of the positive electrode terminal 2 and the opposed part 31 of the negative electrode terminal 3. A width W4 of the projecting part 1b in the Y-axis direction is greater than the laminate width W1. The provision of the positive electrode terminal 2 and the negative electrode terminal 3 can ensure a creepage distance d12 along the respective side and top surfaces of the projecting part 1b and a creepage distance d13 along the respective side and bottom surfaces of the projecting part 1b. The creepage distances d12 and d13 are each in a range of about 5 millimeters or greater and 15 millimeters or smaller, for example.

The opposed part 21 of the positive electrode terminal 2 and the opposed part 31 of the negative electrode terminal 3 interpose a part of the projecting part 1b. An insulating member such as an insulating sheet may be interposed instead between the opposed part 21 of the positive electrode terminal 2 and the opposed part 31 of the negative electrode terminal 3.

A distance (a gap) D1 between the opposed part 21 of the positive electrode terminal 2 and the opposed part 31 of the negative electrode terminal 3 in the Z-axis direction is in a range of about 0.1 millimeters or greater and 4 millimeters or smaller, for example, or may be in a range of about 0.2 millimeters or greater and 4 millimeters or smaller. Setting the distance D1 to about 4 millimeters or smaller can exhibit the effect of reducing the inductance. As the distance D1 is smaller, the inductance can be reduced more effectively. Setting the distance D1 to about 0.1 millimeters or greater can facilitate the step of filling a part of the projecting part 1b between the positive electrode terminal 2 and the negative electrode terminal 3 with the resin material, so as to avoid a partial electrical discharge if air bubbles are caused between the positive electrode terminal 2 and the negative electrode terminal 3.

FIG. 4 is a view, corresponding to the cross section of FIG. 3, illustrating a state in which busbars 5a and 5b are fixed to the respective connection parts 2a and 3a of the positive electrode terminal 2 and the negative electrode terminal 3 by screw fastening. The respective busbars 5a and 5b are electrically connected to a capacitor (not illustrated). A screw 7a is fitted to the connection part 2a of the positive electrode terminal 2 with the busbar 5a and a washer 6a. A screw 7b is fitted to the connection part 3a of the negative electrode terminal 3 with the busbar 5b and a washer 6b. FIG. 4 omits the illustration of nuts fastened to the screws 7a and 7b.

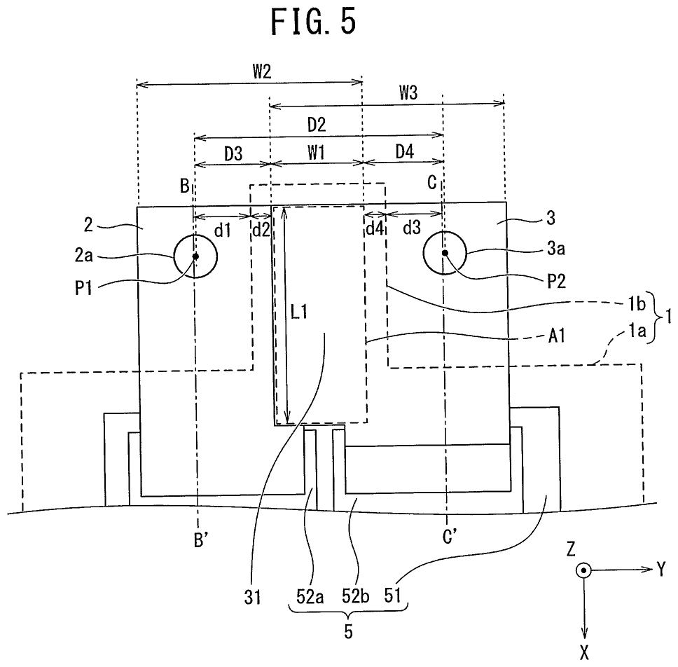

FIG. 5 is a plan view around the positive electrode terminal 2 and the negative electrode terminal 3. FIG. 5 schematically indicates the body part 1a and the projecting part 1b of the sealing resin 1 by the broken line for illustration purposes. Further, FIG. 5 schematically indicates, by the broken line, the opposed area A1 between the opposed part 21 of the positive electrode terminal 2 and the opposed part 31 of the negative electrode terminal 3, as in the case of FIG. 3.

As illustrated in FIG. 5, the opposed area A1, in which the opposed part 21 of the positive electrode terminal 2 and the opposed part 31 of the negative electrode terminal 3 are opposed to each other, has a substantially rectangular shape. The opposed area A1 extends in the X-axis direction from the inside of the body part 1a of the sealing resin 1 toward a region between the connection part 2a of the positive electrode terminal 2 and the connection part 3a of the negative electrode terminal 3. The outer end of the opposed area A1 in the X-axis direction conforms to the respective outer ends of the positive electrode terminal 2 and the negative electrode terminal 3. The inner end of the opposed area A1 may be located on the outside of the body part 1a of the sealing resin 1. A length (a laminate length) L1 of the opposed area A1 in the X-axis direction is in a range of about 10 millimeters or greater and 40 millimeters or smaller, for example.

The centroid (the center) P1 of the connection part 2a of the positive electrode terminal 2 and the centroid (the center) P2 of the connection part 3a of the negative electrode terminal 3 are separated from each other by a distance (a fastening-point distance) D2. The fastening-point distance D2 is in a range of about 13.5 millimeters or greater and 25.5 millimeters or smaller, for example, or may be in a range of about 13.5 millimeters or greater and 21.5 millimeters or smaller, or in a range of about 13.5 millimeters or greater and 17.5 millimeters or smaller.

Setting the fastening-point distance D2 to about 25.5 millimeters or smaller can exhibit the effect of reducing the inductance. The smaller fastening-point distance D2 can further enhance the effect of reducing the inductance. In addition, setting the fastening-point distance D2 to about 13.5 millimeters or greater can ensure an effective area for the screw fastening including the respective connection parts 2a and 3a of the positive electrode terminal 2 and the negative electrode terminal 3.

The greater laminate width W1 can further enhance the effect of reducing the inductance. The smaller fastening-point distance D2 can also increase the effect of reducing the inductance. Considering the relation between the laminate width W1 and the fastening-point distance D2 is an essential matter, since the increase of the laminate width W1 increases the fastening-point distance D2 in order to ensure the effective area for the screw fastening including the respective connection parts 2a and 3a of the positive electrode terminal 2 and the negative electrode terminal 3. Setting the fastening-point distance D2 to a range of about 21.5 millimeters or greater and 25.5 millimeters or smaller can exhibit the effect of reducing the inductance when the laminate width W1 is in a range of about 9 millimeters or greater and 13 millimeters or smaller. Setting the fastening-point distance D2 to a range of about 17.5 millimeters or greater and 21.5 millimeters or smaller can exhibit the effect of reducing the inductance when the laminate width W1 is in a range of about 5 millimeters or greater and 9 millimeters or smaller. Setting the fastening-point distance D2 to a range of about 13.5 millimeters or greater and 17.5 millimeters or smaller can exhibit the effect of reducing the inductance when the laminate width W1 is in a range of about 1 millimeter or greater and 5 millimeters or smaller.

The fastening-point distance D2 is a sum of a distance D3 between the centroid P1 of the connection part 2a and the opposed area A1, a distance D4 between the centroid P2 of the connection part 3a and the opposed area A1, and the laminate width W1 of the opposed area A1, that is, D2=D3+D4+W1. The distances D3 and D4 may be either common to or different from each other. The distances D3 and D4 are each in a range of about 5 millimeters or greater and 12 millimeters or smaller, for example.

The distance D3 is a sum of a distance dl of the effective area for the screw fastening on the outside of the projecting part 1b and a distance d2 on the inside of the projecting part 1b, that is, D3=d1+d2. The distance D4 is a sum of a distance d3 of the effective area for the screw fastening on the outside of the projecting part 1b and a distance d4 on the inside of the projecting part 1b, that is, D4=d3+d4. The distances d1 and d3 may be either common to or different from each other. The distances dl and d3 are each in a range of about 5 millimeters or greater and 12 millimeters or smaller, for example. The distances d2 and d4 may be either common to or different from each other. The distances d2 and d4 are each in a range of about 0.1 millimeters or greater and 2 millimeters or smaller, for example.

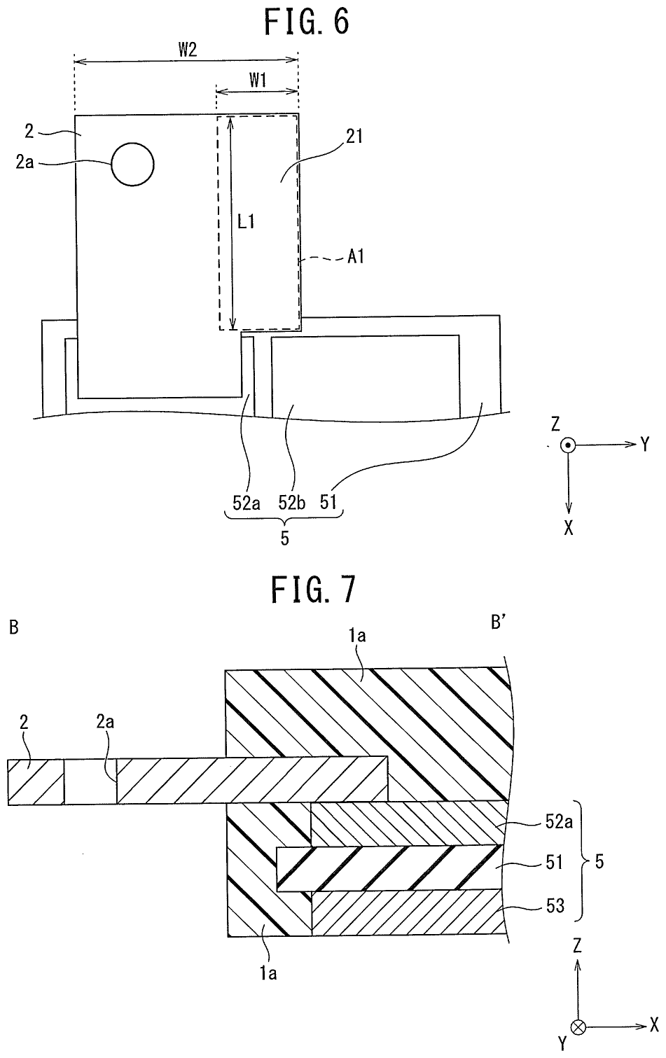

As illustrated in FIG. 5, the negative electrode terminal 3 has an L-like shape in the planar view in which the opposed part 31 protrudes toward the positive electrode terminal 2. FIG. 6 is a plan view omitting the negative electrode terminal 3 illustrated in FIG. 5 so as to show the positive electrode terminal 2 located under the negative electrode terminal 3. As illustrated in FIG. 6, the positive electrode terminal 2 has an L-like shape in the planar view in which the opposed part 21 protrudes toward the negative electrode terminal 3.

FIG. 7 is a cross-sectional view in the X-axis direction parallel to the line B-B′ passing through the connection part 2a of the positive electrode terminal 2 illustrated in FIG. 5. As illustrated in FIG. 5 and FIG. 7, the semiconductor device according to the first embodiment includes an insulated circuit substrate 5. The respective top and side surfaces of the insulated circuit substrate 5 are sealed with the body part 1a of the sealing resin 1, and the bottom surface of the insulated circuit substrate 5 is exposed on the body part 1a of the sealing resin 1. The semiconductor chips 10 illustrated in FIG. 1 are provided on the top surface side of the insulated circuit substrate 5.

The insulated circuit substrate 5 may be a direct copper bonded (DCB) substrate or an active metal brazed (AMB) substrate, for example. The insulated circuit substrate 5 includes an insulating plate 51, conductive plates 52a and 52b deposited on the top surface side of the insulating plate 51, and a conductive plate 53 deposited on the bottom surface side of the insulating plate 51. The insulating plate 51 is a resin insulating layer including polymer material, or a ceramic plate mainly including aluminum oxide (Al₂O₃), aluminum nitride (AlN), silicon nitride (Si₃N₄), or boron nitride (BN), for example. The conductive plates 52a, 52b, and 53 each include conductive material such as copper (Cu), a Cu alloy, aluminum (Al), or an Al alloy, for example.

As illustrated in FIG. 5 and FIG. 7, the positive electrode terminal 2 is provided to be evenly flat from the inside to the outside of the body part 1a of the sealing resin 1, and the inner end part of the positive electrode terminal 2 is bonded to the conductive plate 52a. The shape of the positive electrode terminal 2 in cross section as shown in FIG. 7 can be changed as appropriate. For example, the inner end part of the positive electrode terminal 2 may have a bent part bent into an L-like shape so as to be bonded to the conductive plate 52a.

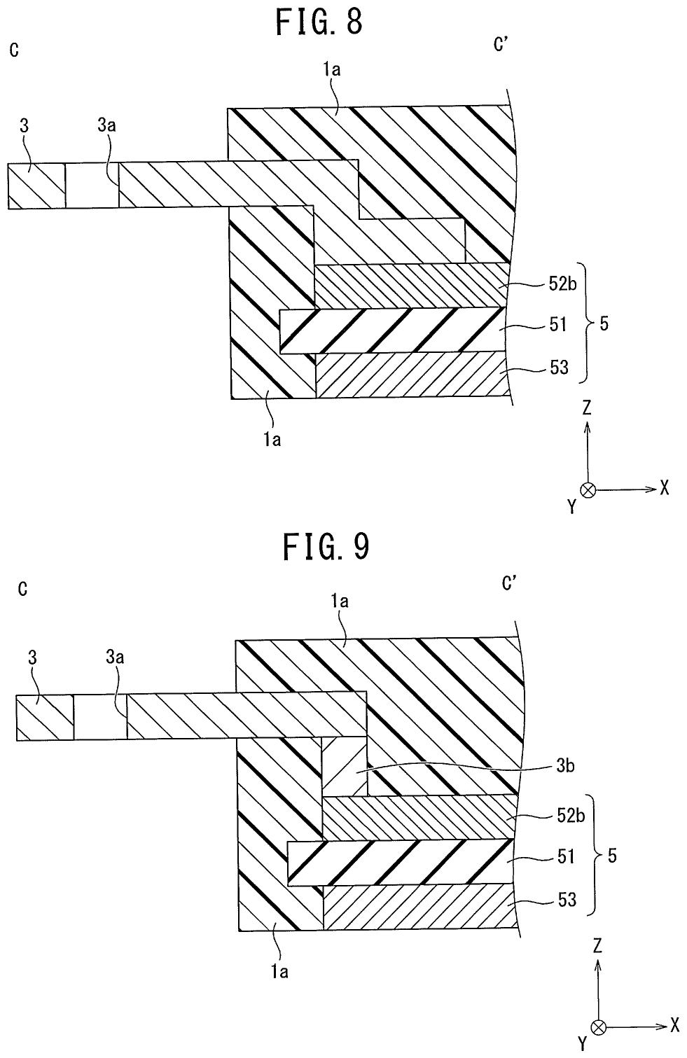

FIG. 8 is a cross-sectional view in the X-axis direction parallel to the line C-C′ passing through the connection part 3a of the negative electrode terminal 3 illustrated in FIG. 5. As illustrated in FIG. 5 and FIG. 8, the inner end part of the negative electrode terminal 3 has a bent part bent into an L-like shape so as to be bonded to the conductive plate 52b. The shape of the negative electrode terminal 3 in cross section as shown in FIG. 8 can be changed as appropriate. For example, the negative electrode terminal 3 may be flat evenly from the inside to the outside of the body part 1a of the sealing resin 1 so that the inner end part of the negative electrode terminal 3 is bonded to the conductive plate 52b via a conductive body 3b such as a copper block, as illustrated in FIG. 9.

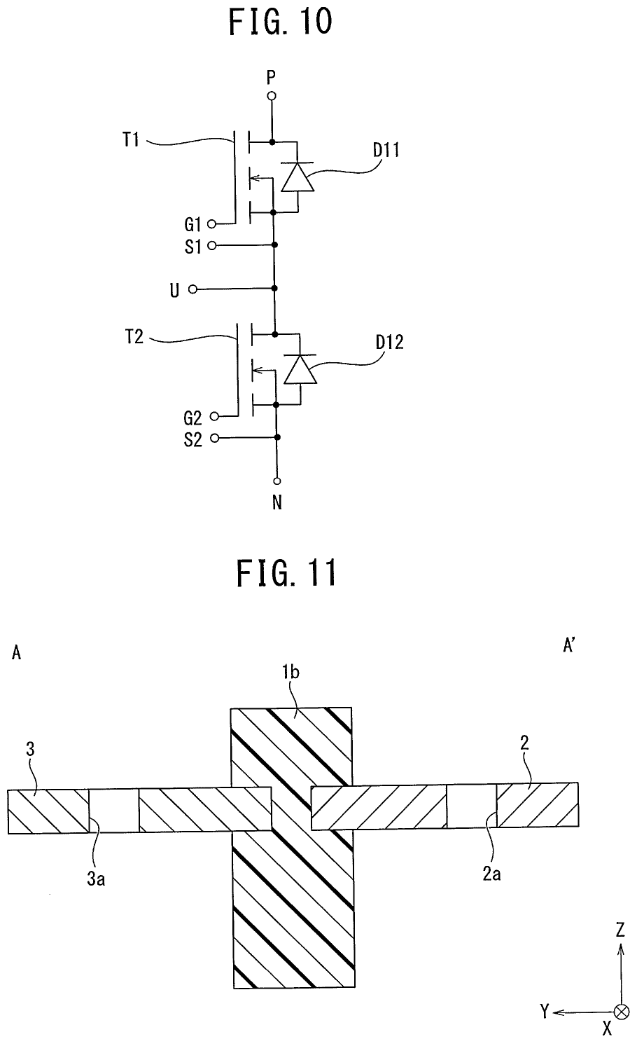

FIG. 10 is an equivalent circuit diagram of the semiconductor device according to the first embodiment. As illustrated in FIG. 10, the semiconductor device according to the first embodiment implements a part of a three-phase bridge circuit. A drain electrode of a transistor T1 on the upper-arm side is connected to a positive electrode terminal P, and a source electrode of a transistor T2 on the lower-arm side is connected to a negative electrode terminal N. A source electrode of the transistor T1 and a drain electrode of the transistor T2 are connected to an output terminal U and an auxiliary source terminal S1. An auxiliary source terminal S2 is connected to the source electrode of the transistor T2. Gate control terminals G1 and G2 are connected to gate electrodes of the respective transistors T1 and T2. Body diodes D11 and D12 each serving as a freewheeling diode (FWD) are internally provided and connected in antiparallel to the transistors T1 and T2.

The positive electrode terminal P, the negative electrode terminal N, and the output terminal U illustrated in FIG. 10 respectively correspond to the positive electrode terminal 2, the negative electrode terminal 3, and the output terminal 4 illustrated in FIG. 1 to FIG. 9. The transistors T1 and T2 and the body diodes D11 and D12 illustrated in FIG. 10 correspond to the semiconductor chips 10 illustrated in FIG. 1. FIG. 1 to FIG. 9 omit the illustration of the respective configurations corresponding to the gate control terminals G1 and G2 and the auxiliary source terminals S1 and S2 illustrated in FIG. 10.

### Method of Manufacturing Semiconductor Device

An example of a method of manufacturing (assembling) the semiconductor device according to the first embodiment is described below. The semiconductor chips 10, the output terminal 4, the positive electrode terminal 2, and the negative electrode terminal 3 are bonded onto the top surface side of the insulated circuit substrate 5 via bonding material such as solder or sintered material. The insulated circuit substrate 5, the semiconductor chips 10, the output terminal 4, the positive electrode terminal 2, and the negative electrode terminal 3 are arranged to be electrically connected to each other by use of bonding wires, lead frames, or a printed substrate (each not illustrated), for example. Thereafter, the insulated circuit substrate 5 and the semiconductor chips 10 are sealed with the sealing resin 1 by transfer molding, and each of the positive electrode terminal 2, the negative electrode terminal 3, and the output terminal 4 are further partly sealed with the sealing resin 1. The semiconductor device according to the first embodiment is thus completed.

### First Comparative Example

A semiconductor device of a first comparative example is described below. FIG. 11 is a cross-sectional view illustrating the semiconductor device of the first comparative example, corresponding to the cross-sectional view of the semiconductor device according to the first embodiment in FIG. 3. FIG. 12 is a plan view illustrating the semiconductor device of the first comparative example, corresponding to the plan view of the semiconductor device according to the first embodiment in FIG. 5. As illustrated in FIG. 11 and FIG. 12, the semiconductor device of the first comparative example differs from the semiconductor device according to the first embodiment in that the positive electrode terminal 2 and the negative electrode terminal 3 are arranged separately from each other in the Y-axis direction.

The demand has grown for next-generation semiconductor devices with a structure that can lead to a small size/low profile and low inductance and further allow a choice between screw fastening and laser welding for terminal connection. The semiconductor device of the first comparative example has the structure that enables the low-height profile but inevitably increases the inductance, since no opposed part is provided between the positive electrode terminal 2 and the negative electrode terminal 3. In contrast, as illustrated in FIG. 3 and FIG. 5, the semiconductor device according to the first embodiment includes the opposed area A1 between the opposed part 21 of the positive electrode terminal 2 and the opposed part 31 of the negative electrode terminal 3, so as to enable the structure with the low-height profile and low inductance.

### Second Comparative Example

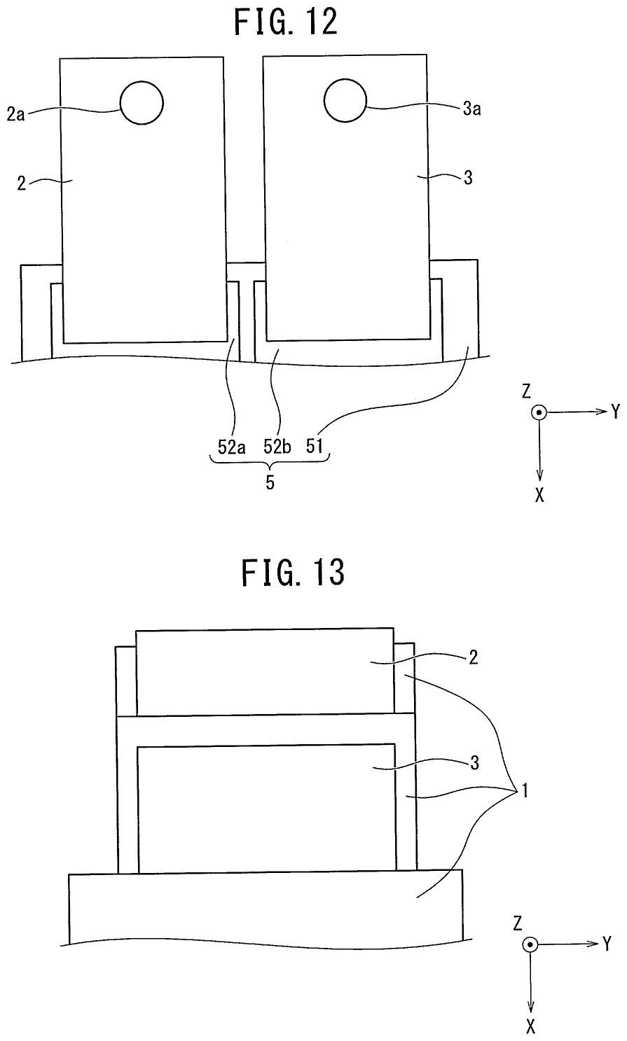

A semiconductor device of a second comparative example is described below. FIG. 13 is a plan view illustrating the semiconductor device of the second comparative example, corresponding to the plan view of the semiconductor device according to the first embodiment illustrated in FIG. 5. As illustrated in FIG. 13, the semiconductor device of the second comparative example differs from the semiconductor device according to the first embodiment in that the positive electrode terminal 2 and the negative electrode terminal 3 are opposed adjacent to each other (laminated together) such that the end part of the positive electrode terminal 2 protrudes further to the outside of the end part of the negative electrode terminal 3 in the X-axis direction.

The structure of the semiconductor device of the second comparative example, in which the positive electrode terminal 2 and the negative electrode terminal 3 are opposed to each other, can lead to low inductance. This structure, however, limits the way of the connection between the positive electrode terminal 2 and the negative electrode terminal 3 to laser welding, since the positive electrode terminal 2 and the negative electrode terminal 3 cannot be connected to an external member by screw fastening. The laser welding inevitably increases the size of the module in order to ensure the effective area and the thickness of the terminals, and further hinders a tolerance control for avoiding penetration of the terminals, which decreases productivity accordingly. In contrast, as illustrated in FIG. 3 and FIG. 5, the configuration of the semiconductor device according to the first embodiment, in which the opposed part 21 of the positive electrode terminal 2 and the opposed part 31 of the negative electrode terminal 3 are opposed to each other to provide the opposed area A1 between the respective connection parts 2a and 3a, enables the screw fastening for connecting the positive electrode terminal 2 and the negative electrode terminal 3 together, so as to allow the choice between the screw fastening and the laser welding for the connection between the positive electrode terminal 2 and the negative electrode terminal 3.

### EXAMPLES

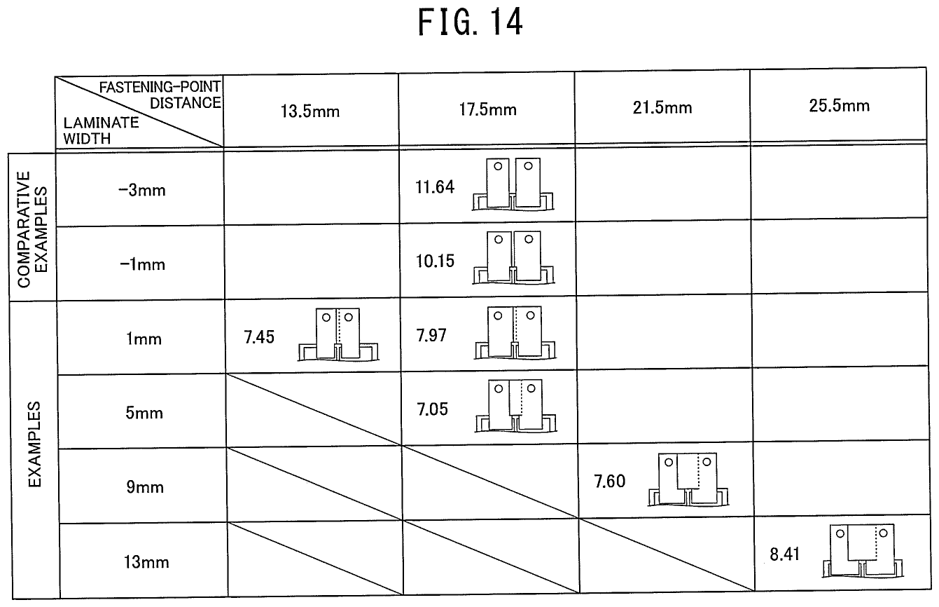

FIG. 14 is a table showing simulation results regarding inductances (unit: nH), executed for examples of the semiconductor device according to the first embodiment, and comparative examples in which the laminate width and the fastening-point distance are changed, under the common conditions with respect to the other elements. FIG. 14 shows the inductance values and also the schematic positional relations between the positive electrode terminal 2 and the negative electrode terminal 3 when the laminate width and the fastening-point distance are changed.

The two comparative examples shown in FIG. 14 has a structure corresponding to the semiconductor device of the first comparative example illustrated in FIG. 11 and FIG. 12, in which the positive electrode terminal 2 and the negative electrode terminal 3 are arranged separately from each other. The negative values indicated for the laminate width each show a distance by which the positive electrode terminal 2 and the negative electrode terminal 3 are separated. One of the comparative examples has an inductance that is 11.64 nH when the laminate width is −3 millimeters and the fastening-point distance is 17.5 millimeters. The other comparative example has an inductance that is 10.15 nH when the laminate width is −1 millimeter and the fastening-point distance is 17.5 millimeters.

A first example has an inductance that is 7.45 nH when the laminate width is 1 millimeter and the fastening-point distance is 13.5 millimeters. A second example has an inductance that is 7.97 nH when the laminate width is 1 millimeter and the fastening-point distance is 17.5 millimeters. A third example has an inductance that is 7.05 nH when the laminate width is 5 millimeters and the fastening-point distance is 17.5 millimeters. A fourth example has an inductance that is 7.60 nH when the laminate width is 9 millimeters and the fastening-point distance is 21.5 millimeters. A fifth example has an inductance that is 8.41 nH when the laminate width is 13 millimeters and the fastening-point distance is 25.5 millimeters. The respective examples thus can achieve a reduction in inductance more than the comparative examples.

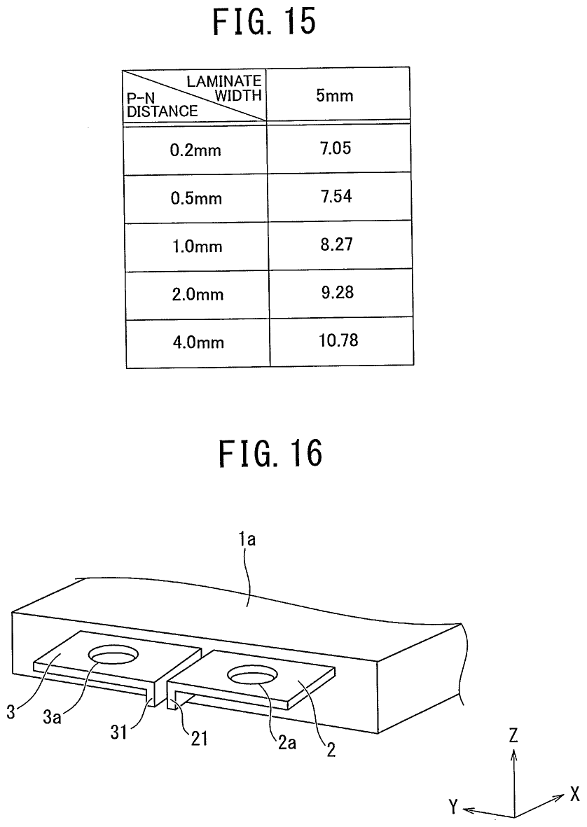

FIG. 15 is a table showing simulation results regarding inductances (unit: nH) in one of the examples shown in FIG. 14, in which the laminate width is 5 millimeters and the fastening-point distance is 17.5 millimeters, when the gap (the P-N distance) D1 between the opposed part 21 of the positive electrode terminal 2 and the opposed part 31 of the negative electrode terminal 3 is changed to 0.2 millimeters, 0.5 millimeters, 1.0 millimeters, 2.0 millimeters, and 4.0 millimeters. The simulation results revealed, as shown in FIG. 15, that the inductance can be reduced as the P-N distance is smaller.

As described above, the semiconductor device according to the first embodiment has the configuration provided with the opposed area A1, in which the opposed part 21 of the positive electrode terminal 2 and the opposed part 31 of the negative electrode terminal 3 are opposed, between the connection part 2a of the positive electrode terminal 2 and the connection part 3a of the negative electrode terminal 3, so as to enable the screw fastening for connecting the positive electrode terminal 2 and the negative electrode terminal 3 to the external member while achieving a reduction in inductance.

### Second Embodiment

FIG. 16 is a perspective view illustrating a semiconductor device according to a second embodiment, corresponding to the perspective view of the semiconductor device according to the first embodiment illustrated in FIG. 2. FIG. 17 is a cross-sectional view illustrating the semiconductor device according to the second embodiment, corresponding to the cross-sectional view of the semiconductor device according to the first embodiment illustrated in FIG. 3. As illustrated in FIG. 16 and FIG. 17, the semiconductor device according to the second embodiment differs from the semiconductor device according to the first embodiment in that the positive electrode terminal 2 and the negative electrode terminal 3 are each bent in the Z-axis direction at positions adjacent to each other so as to provide an opposed area A2 in which the opposed part 21 of the positive electrode terminal 2 and the opposed part 31 of the negative electrode terminal 3 are opposed in the Y-axis direction.

As illustrated in FIG. 16 and FIG. 17, the opposed part 21 of the positive electrode terminal 2 and the opposed part 31 of the negative electrode terminal 3 are bent in the common direction in the reverse direction of the Z axis. A gap D5 between the opposed part 21 of the positive electrode terminal 2 and the opposed part 31 of the negative electrode terminal 3 in the Y-axis direction illustrated in FIG. 17 is set similarly to the gap D1 between the opposed part 21 of the positive electrode terminal 2 and the opposed part 31 of the negative electrode terminal 3 in the Z-axis direction in the semiconductor device according to the first embodiment. A laminate width W5 of the opposed area A2 between the opposed part 21 of the positive electrode terminal 2 and the opposed part 31 of the negative electrode terminal 3 in the Z-axis direction is set similarly to the laminate width W1 of the opposed area A1 in the Y-axis direction in the semiconductor device according to the first embodiment.

FIG. 16 only illustrates the body part 1a of the sealing resin 1 while omitting the illustration of the projecting part 1b projecting from the body part 1a. As illustrated in FIG. 17, the projecting part 1b of the sealing resin 1 is provided to cover the opposed part 21 of the positive electrode terminal 2 and the opposed part 31 of the negative electrode terminal 3. The other configurations of the semiconductor device according to the second embodiment are substantially the same as those of the semiconductor device according to the first embodiment, and overlapping explanations are not repeated below.

The semiconductor device according to the second embodiment has the configuration provided with the opposed area A2, in which the opposed part 21 of the positive electrode terminal 2 and the opposed part 31 of the negative electrode terminal 3 are opposed, between the connection part 2a of the positive electrode terminal 2 and the connection part 3a of the negative electrode terminal 3, so as to enable the screw fastening for connecting the positive electrode terminal 2 and the negative electrode terminal 3 to the external member while achieving a reduction in inductance.

Further, the configuration of the semiconductor device according to the second embodiment provided with the opposed area A2 in which the opposed part 21 of the positive electrode terminal 2 and the opposed part 31 of the negative electrode terminal 3 are opposed in the Y-axis direction, can avoid an increase in the fastening-point distance D6 in the Y-axis direction regardless of whether the laminate width W5 in the Z-axis direction is increased, so as to further reduce the inductance accordingly.

### Third Embodiment

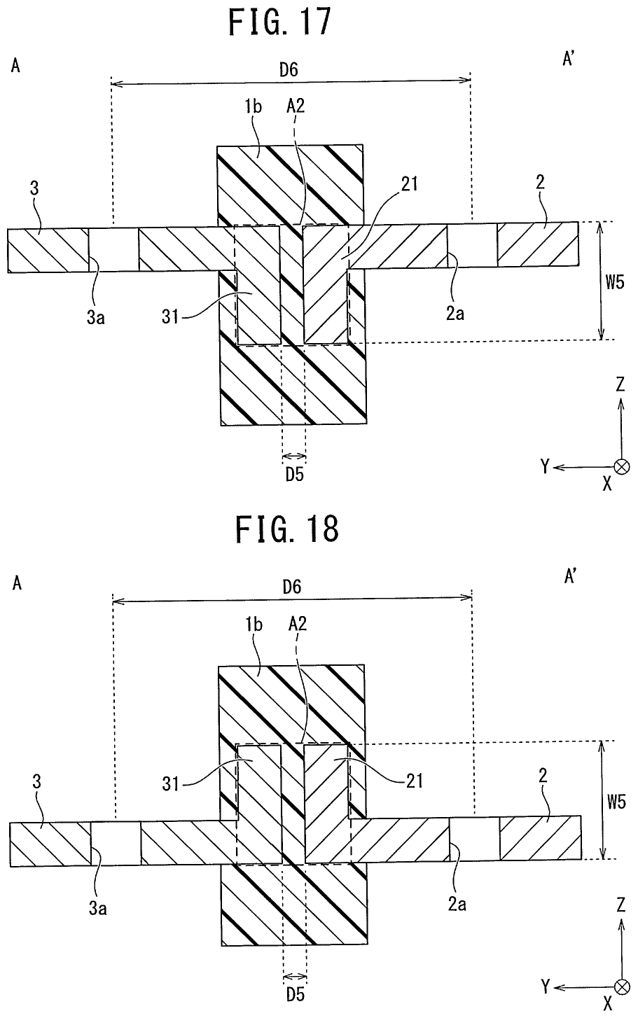

FIG. 18 is a cross-sectional view illustrating a semiconductor device according to a third embodiment, corresponding to the cross-sectional view of the semiconductor device according to the first embodiment illustrated in FIG. 3. As illustrated in FIG. 18, the semiconductor device according to the third embodiment has a configuration similar to that of the semiconductor device according to the second embodiment in that the positive electrode terminal 2 and the negative electrode terminal 3 are each bent in the Z-axis direction at the positions adjacent to each other so as to provide the opposed area A2 in which the opposed part 21 of the positive electrode terminal 2 and the opposed part 31 of the negative electrode terminal 3 are opposed in the Y-axis direction. The semiconductor device according to the third embodiment differs from the semiconductor device according to the second embodiment in that the opposed part 21 of the positive electrode terminal 2 and the opposed part 31 of the negative electrode terminal 3 are bent in the common direction that is the forward direction of the Z axis. The other configurations of the semiconductor device according to the third embodiment are substantially the same as those of the semiconductor device according to the second embodiment, and overlapping explanations are not repeated below.

The semiconductor device according to the third embodiment has the configuration provided with the opposed area A2, in which the opposed part 21 of the positive electrode terminal 2 and the opposed part 31 of the negative electrode terminal 3 are opposed, between the connection part 2a of the positive electrode terminal 2 and the connection part 3a of the negative electrode terminal 3, so as to enable the screw fastening for connecting the positive electrode terminal 2 and the negative electrode terminal 3 to the external member while achieving a reduction in inductance.

Further, the configuration of the semiconductor device according to the third embodiment provided with the opposed area A2 in which the opposed part 21 of the positive electrode terminal 2 and the opposed part 31 of the negative electrode terminal 3 are opposed in the Y-axis direction, can avoid an increase in the fastening-point distance D6 in the Y-axis direction regardless of whether the laminate width W5 in the Z-axis direction is increased, so as to further reduce the inductance accordingly.

### Fourth Embodiment

FIG. 19 is a cross-sectional view illustrating a semiconductor device according to a fourth embodiment, corresponding to the cross-sectional view of the semiconductor device according to the first embodiment illustrated in FIG. 3. As illustrated in FIG. 19, the semiconductor device according to the fourth embodiment has a configuration similar to that of the semiconductor device according to the second embodiment in that the positive electrode terminal 2 and the negative electrode terminal 3 are each bent in the Z-axis direction at the positions adjacent to each other so as to provide the opposed area A2 in which the opposed part 21 of the positive electrode terminal 2 and the opposed part 31 of the negative electrode terminal 3 are opposed in the Y-axis direction. The semiconductor device according to the fourth embodiment differs from the semiconductor device according to the second embodiment in that the opposed part 21 of the positive electrode terminal 2 and the opposed part 31 of the negative electrode terminal 3 are bent in the opposite directions that are the respective forward and reverse directions of the Z axis. The other configurations of the semiconductor device according to the fourth embodiment are substantially the same as those of the semiconductor device according to the second embodiment, and overlapping explanations are not repeated below.

The semiconductor device according to the fourth embodiment has the configuration provided with the opposed area A2, in which the opposed part 21 of the positive electrode terminal 2 and the opposed part 31 of the negative electrode terminal 3 are opposed, between the connection part 2a of the positive electrode terminal 2 and the connection part 3a of the negative electrode terminal 3, so as to enable the screw fastening for connecting the positive electrode terminal 2 and the negative electrode terminal 3 to the external member while achieving a reduction in inductance.

Further, the configuration of the semiconductor device according to the fourth embodiment provided with the opposed area A2 in which the opposed part 21 of the positive electrode terminal 2 and the opposed part 31 of the negative electrode terminal 3 are opposed in the Y-axis direction, can avoid an increase in the fastening-point distance D6 in the Y-axis direction regardless of whether the laminate width W5 in the Z-axis direction is increased, so as to further reduce the inductance accordingly.

### Fifth Embodiment

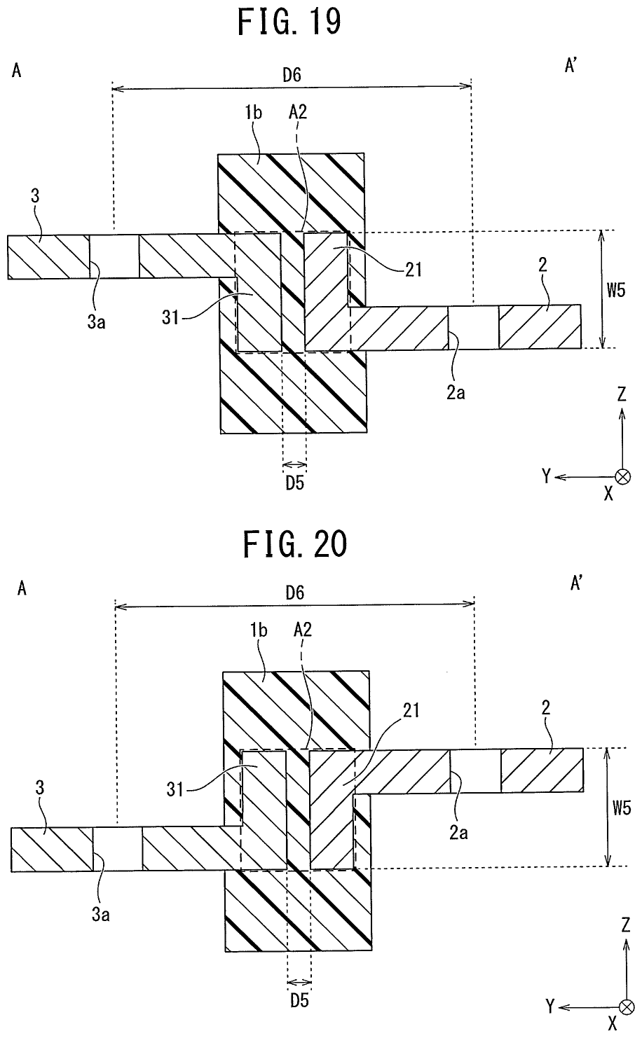

FIG. 20 is a cross-sectional view illustrating a semiconductor device according to a fifth embodiment, corresponding to the cross-sectional view of the semiconductor device according to the first embodiment illustrated in FIG. 3. As illustrated in FIG. 20, the semiconductor device according to the fifth embodiment has a configuration similar to that of the semiconductor device according to the second embodiment in that the positive electrode terminal 2 and the negative electrode terminal 3 are each bent in the Z-axis direction at the positions adjacent to each other so as to provide the opposed area A2 in which the opposed part 21 of the positive electrode terminal 2 and the opposed part 31 of the negative electrode terminal 3 are opposed in the Y-axis direction. The semiconductor device according to the fifth embodiment differs from the semiconductor device according to the second embodiment in that the opposed part 21 of the positive electrode terminal 2 and the opposed part 31 of the negative electrode terminal 3 are bent in the opposite directions that are the respective reverse and forward directions of the Z axis. The other configurations of the semiconductor device according to the fifth embodiment are substantially the same as those of the semiconductor device according to the second embodiment, and overlapping explanations are not repeated below.

The semiconductor device according to the fifth embodiment has the configuration provided with the opposed area A2, in which the opposed part 21 of the positive electrode terminal 2 and the opposed part 31 of the negative electrode terminal 3 are opposed, between the connection part 2a of the positive electrode terminal 2 and the connection part 3a of the negative electrode terminal 3, so as to enable the screw fastening for connecting the positive electrode terminal 2 and the negative electrode terminal 3 to the external member while achieving a reduction in inductance.

Further, the configuration of the semiconductor device according to the fifth embodiment provided with the opposed area A2 in which the opposed part 21 of the positive electrode terminal 2 and the opposed part 31 of the negative electrode terminal 3 are opposed in the Y-axis direction, can avoid an increase in the fastening-point distance D6 in the Y-axis direction regardless of whether the laminate width W5 in the Z-axis direction is increased, so as to further reduce the inductance accordingly.

### Sixth Embodiment

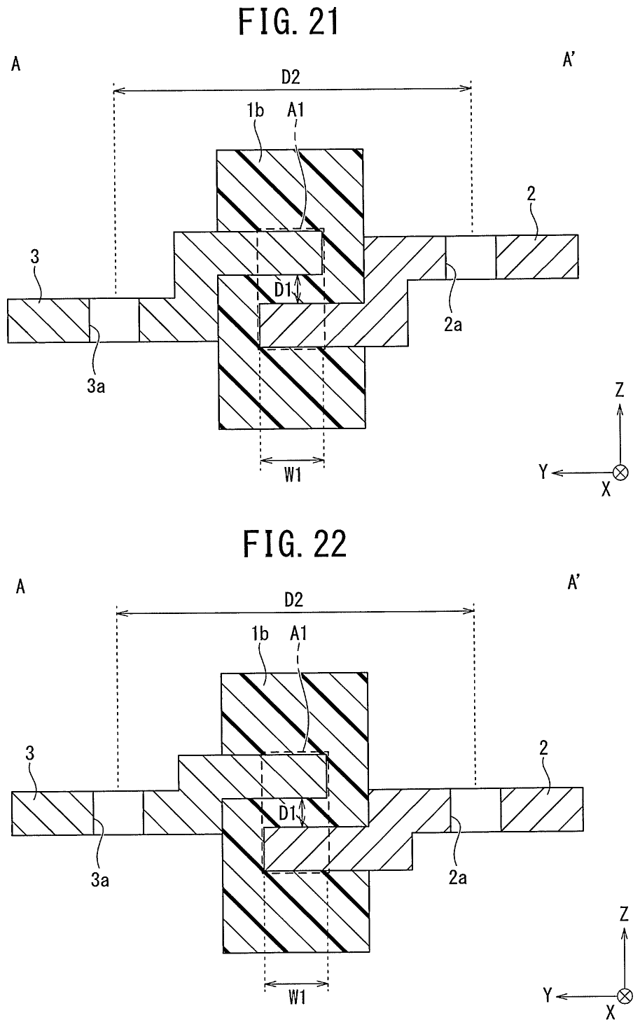

FIG. 21 is a cross-sectional view illustrating a semiconductor device according to a sixth embodiment, corresponding to the cross-sectional view of the semiconductor device according to the first embodiment illustrated in FIG. 3. As illustrated in FIG. 21, the semiconductor device according to the sixth embodiment differs from the semiconductor device according to the first embodiment in that the positive electrode terminal 2 and the negative electrode terminal 3 each have an inverted N-like shape in cross section. The other configurations of the semiconductor device according to the sixth embodiment are substantially the same as those of the semiconductor device according to the first embodiment, and overlapping explanations are not repeated below.

The semiconductor device according to the sixth embodiment has the configuration provided with the opposed area A1, in which the opposed part 21 of the positive electrode terminal 2 and the opposed part 31 of the negative electrode terminal 3 are opposed, between the connection part 2a of the positive electrode terminal 2 and the connection part 3a of the negative electrode terminal 3, so as to enable the screw fastening for connecting the positive electrode terminal 2 and the negative electrode terminal 3 to the external member while achieving a reduction in inductance.

### Seventh Embodiment

FIG. 22 is a cross-sectional view illustrating a semiconductor device according to a seventh embodiment, corresponding to the cross-sectional view of the semiconductor device according to the first embodiment illustrated in FIG. 3. As illustrated in FIG. 22, the semiconductor device according to the seventh embodiment has a configuration similar to that of the semiconductor device according to the sixth embodiment in that the positive electrode terminal 2 and the negative electrode terminal 3 each have the inverted N-like shape in cross section. The semiconductor device according to the seventh embodiment differs from the semiconductor device according to the sixth embodiment in that the respective connection parts 2a and 3a of the positive electrode terminal 2 and the negative electrode terminal 3 are located at the same level in the Z-axis direction. The other configurations of the semiconductor device according to the seventh embodiment are substantially the same as those of the semiconductor device according to the sixth embodiment, and overlapping explanations are not repeated below.

The semiconductor device according to the seventh embodiment has the configuration provided with the opposed area A1, in which the opposed part 21 of the positive electrode terminal 2 and the opposed part 31 of the negative electrode terminal 3 are opposed, between the connection part 2a of the positive electrode terminal 2 and the connection part 3a of the negative electrode terminal 3, so as to enable the screw fastening for connecting the positive electrode terminal 2 and the negative electrode terminal 3 to the external member while achieving a reduction in inductance.

Further, the configuration of the semiconductor device according to the seventh embodiment, in which the positive electrode terminal 2 and the negative electrode terminal 3 have the same shape in cross section, and the positions provided with the respective connection parts 2a and 3a of the positive electrode terminal 2 and the negative electrode terminal 3 are located at the same level in the Z-axis direction, can facilitate the standardization of manufacture of the components used for the positive electrode terminal 2 and the negative electrode terminal 3.

### Other Embodiments

While the present disclosure has been described above by reference to the first to seventh embodiments, it should be understood that the present disclosure is not intended to be limited to the descriptions and the drawings composing part of this disclosure. Various alternative embodiments, examples, and technical applications will be apparent to those skilled in the art according to this disclosure.

While the first embodiment is illustrated above with the case in which the positive electrode terminal 2 is located on the lower side and the negative electrode terminal 3 is located on the upper side in the Z-axis direction, this positional relation in the Z-axis direction may be reversed. Further, while the sixth and seventh embodiments are illustrated above with the case in which the positive electrode terminal 2 and the negative electrode terminal 3 each have the inverted N-like shape in cross section, the positive electrode terminal 2 and the negative electrode terminal 3 may each have an N-like shape in cross section. Further, the first to seventh embodiments may include the positive electrode terminal 2 and the negative electrode terminal 3 arranged at the positions opposite to each other.

Further, the configurations disclosed in the first to seventh embodiments may be combined as appropriate within a range that does not contradict with the scope of the first to seventh embodiments. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. A semiconductor device comprising:
a semiconductor chip;
a sealing resin provided to seal the semiconductor chip;
a first terminal extending from the sealing resin in a first direction so as to have a first connection part projecting to an outside of the sealing resin; and
a second terminal extending from the sealing resin in the first direction so as to have a second connection part projecting to the outside of the sealing resin,
wherein the first terminal and the second terminal have rectangular opposed parts separately opposed to each other between the first connection part and the second connection part, and
the respective opposed parts have a width in a range of 1 millimeter or greater and 13 millimeters or smaller in a second direction perpendicular to the first direction.

2. The semiconductor device of claim 1, wherein the width of the respective opposed parts in the second direction is 9 millimeters or smaller.

3. The semiconductor device of claim 1, wherein a gap between the respective opposed parts of the first terminal and the second terminal is 4 millimeters or smaller.

4. The semiconductor device of claim 1, wherein a distance between the first connection part and the second connection part is 25.5 millimeters or smaller.

5. The semiconductor device of claim 1, wherein:
the second direction is parallel to a main surface of each of the first terminal and the second terminal;
the first terminal and the second terminal are shifted from each other in a third direction perpendicular to each of the first direction and the second direction; and
the respective opposed parts of the first terminal and the second terminal are opposed to each other in the third direction perpendicular to each of the first direction and the second direction.

6. The semiconductor device of claim 1, wherein:
the second direction is perpendicular to a main surface of each of the first terminal and the second terminal; and
the respective opposed parts of the first terminal and the second terminal are bent in the second direction at a position at which the first terminal and the second terminal are located adjacent to each other so as to be opposed to each other in a third direction perpendicular to each of the first direction and the second direction.

7. The semiconductor device of claim 6, wherein the respective opposed parts of the first terminal and the second terminal are bent in a common direction.

8. The semiconductor device of claim 6, wherein the respective opposed parts of the first terminal and the second terminal are bent in opposite directions.

9. The semiconductor device of claim 1, wherein the sealing resin includes a projecting part covering the respective opposed parts of the first terminal and the second terminal.

10. The semiconductor device of claim 9, wherein the projecting part extends from the sealing resin outward farther than the first terminal and the second terminal in the first direction.
